(19) United States
(12) Patent Application Publication
(10) Pub. No.: US 2008/0112450 A1
(43) Pub. Date: May 15, 2008

(54) Homogeneous-Beam Temperature-Stable Semiconductor Laser and Method of Production

(75) Inventor: Michel Krakowski, Bourg La Reine (FR)

Correspondence Address: LOWE HAUPTMAN & BERNER, LLP, 1700 DIAGONAL ROAD, SUITE 300, ALEXANDRIA, VA, 22314, US

(73) Assignee: Thales, Neuilly Sur Seine (FR)

(21) Appl. No.: 11/722,561

(22) PCT Filed: Dec. 21, 2005
(86) PCT No.: PCT/EP05/57005

§ 371 Date: Jun. 22, 2007

(30) Foreign Application Priority Data
Dec. 22, 2004 (FR) 04/13742

(51) Int. Cl. H01S 5/00

(52) U.S. Cl. 372/45.01

(57) ABSTRACT

The semiconductor laser according to the invention is characterized in that it comprises, in an active layer, a first part (7) in the form of a narrow monomode stripe with transverse gain guiding, terminating in a second part (8) flaring out from the first part, also with transverse gain guiding.

The present invention relates to a homogenous-beam temperature-stable semiconductor laser, and also to a method of producing a laser of this type.

Semiconductor lasers with a power of greater than 1 watt are generally lasers of the broad stripe type and, depending on the required emission power, may be unitary lasers or lasers arranged in parallel to form arrays. The main drawback of such lasers is that the amplitude distribution of their emitted beam in a plane perpendicular to their emission face is highly divergent (with a divergence of around 15° in a plane parallel to the active layers) and very inhomogeneous. This results in a reduction in the efficiency of coupling to an optical fiber. The cause of this is the existence of parasitic modes in the laser cavity and the presence of “filamentation” defects (the electron current within the semiconductor does not pass through the entire active section of the semiconductor, but through one point in this section).

To improve the homogeneity of the near field of the emission face of such lasers, a monomode narrow stripe laser (acting as a filter), extended by a flared part acting as an amplifier, is integrated on the same chip. Power levels substantially above 1 watt can then be emitted, while maintaining a monomode transverse beam. The known lasers have been produced in the following two configurations. The first consists in etching, in active layers, a narrow monomode stripe with transverse index guiding followed by a flared part, which also has transverse index guiding, where “transverse index guiding” means that the lateral confinement of the optical field is achieved by differentiation of the refractive index between the narrow stripe zone and the zones bordering the stripe. The second configuration also includes a narrow monomode stripe with transverse index guiding, but followed by a flared part with transverse gain guiding. Hitherto, no other configuration has been proposed, as it was considered that only the two aforementioned configurations allow the quality of the laser beam emitted to be easily controlled. However, these known structures are relatively complex to produce and their dissipated heat is not easy to extract.

A semiconductor laser is known from U.S. Pat. No. 6,272,162 that comprises a first part in the form of a narrow stripe and a flared terminal second part. Apart from the fact that this known laser includes, between these two parts, “pumping stripes” separated by high-resistance zones, the narrow stripe is deposited after having etched out the active layers by chemical etching, whereas the flared part is bounded by ion implantation in the zones that border it. This results in a complex, lengthy and expensive fabrication process.

The subject of the present invention is a semiconductor laser, the emitted beam of which has a low divergence, is homogeneous and has a power of greater than about 1 W, while being temperature-stable, which laser is easy to produce, which may have good thermal dissipation and which can be fabricated in groups of several elements on the same substrate.

The semiconductor laser according to the invention is characterized in that its cavity comprises, in an active layer, a first part in the form of a narrow monomode stripe with transverse gain guiding, terminating in a second part flaring out from the first part, also with transverse gain guiding.

The method of the invention is a method of producing a semiconductor laser comprising a first part in the form of a narrow stripe and being extended by a second part flaring out from the first part, characterized in that it comprises the following steps:
epitaxial growth of the substrate and the following active and confinement layers, and also of an upper electrical contact layer;
deposition of an ohmic contact on the upper electrical contact layer;
thinning of the underside of the substrate;
deposition of an ohmic contact on the underside of the substrate;
deposition of a photoresist on the ohmic contact and photolithography, leaving photoresist remaining on top of a zone corresponding to said two parts of the laser;
proton implantation via the upper face of the assembly comprising the substrate and the layers formed thereon; and
deposition of an electrode on the ohmic contact.

The present invention will be more clearly understood on reading the detailed description of one embodiment, given by way of nonlimiting example and illustrated by the appended drawing in which:

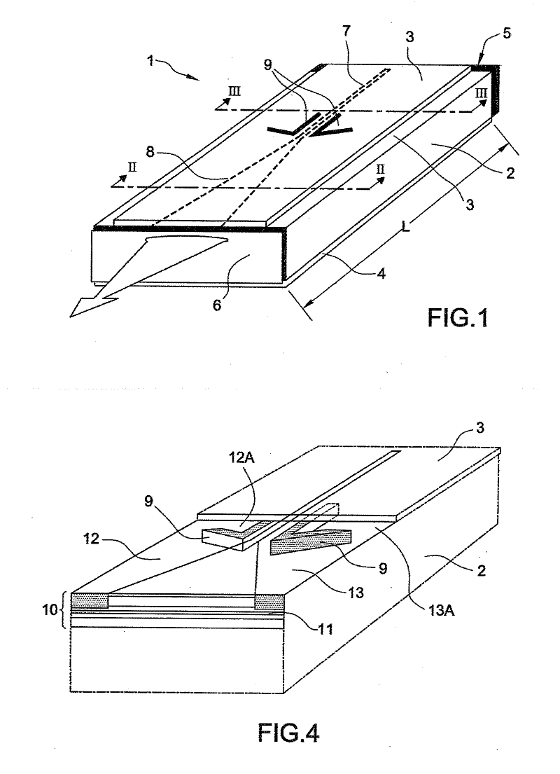

FIG. 1 is a simplified view in perspective of a laser according to the invention;

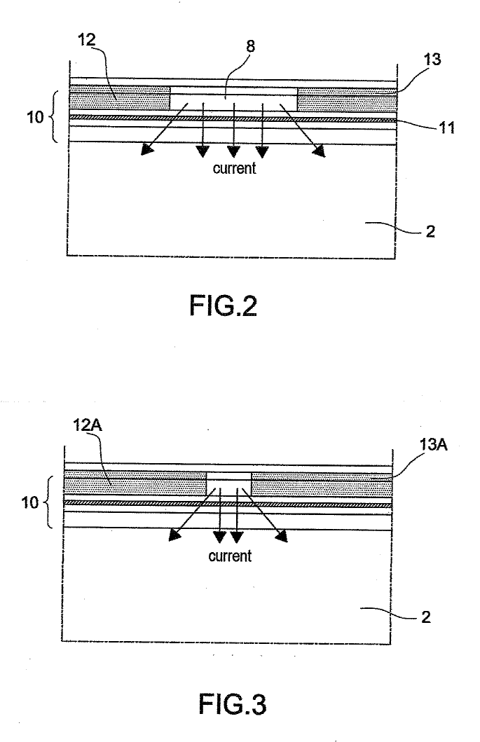

FIG. 2 is a sectional view, on II-II of FIG. 1, of the flared part of the laser of FIG. 1 associated with which is a plot of the variation of the optical index along this section;

FIG. 3 is a sectional view, on III-III of FIG. 1, of the flared part of the laser of FIG. 1 associated with which is a plot of the variation of the optical index along this section;

FIG. 4 is a simplified view in perspective, with a cutaway showing a detail of the construction of a deflector of the laser of FIG. 1;

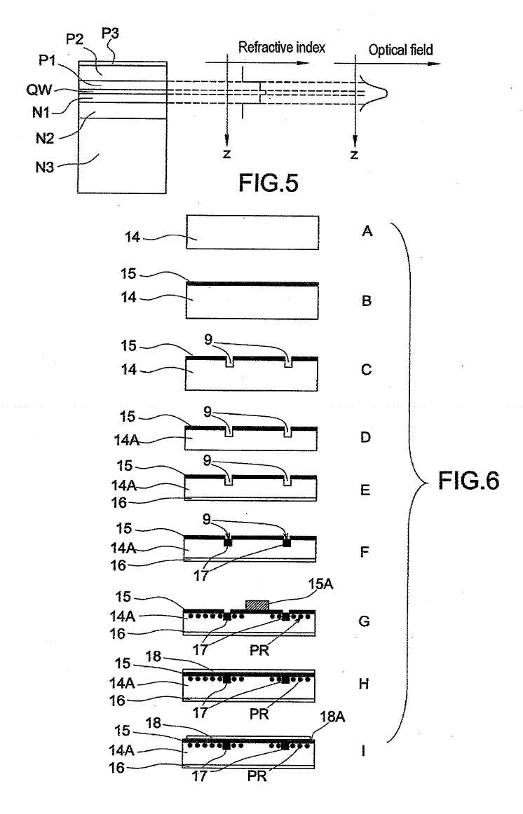

FIG. 5 is a schematic sectional view showing the various confinement and active layers of the laser of FIG. 1; and

FIG. 6 is a set of nine highly simplified sectional views showing the various steps in the fabrication of the laser of the invention.

The semiconductor laser 1 shown in FIG. 1 is an elementary laser source, but it should be clearly understood that it is possible to form an array comprising several such elementary sources side by side, which are formed in the same semiconductor rod. The laser 1 is in the form of a semiconductor rod 2 of rectangular parallelepipedal shape. Electrodes 3 and 4 are formed on the two large faces of the rod 2. One of the two small lateral faces, referenced 5, is treated so as to have a very high reflectivity at the operating wavelength of the laser. The other small lateral face, referenced 6, which is the emissive face of the laser, undergoes an antireflection treatment. Formed in the transverse guiding layers (described in detail below) of the rod 2 are, parallel to the long axis of the rod 2, is a “current flow channel” or narrow monomode stripe 7 which is extended by a flared region 8 terminating in the face 6. The flare angle of the part 8 is about 1 to 2 degrees. The width of the stripe 7 is a few microns. According to a first exemplary embodiment, the length L of the rod is about 2.5 to 3 mm, the flare angle of the part 8 is about 2° and its length is about 1 mm. According to another exemplary embodiment, the length L is also about 2.5 to 3 mm, the flare angle of the part 8 is about 0.64° and its length is about 2.2 mm. In fact, this stripe 7 and its flared extension 8 have not been depicted, but they correspond to conducting zones of the active region of the rod 2, along the axis of which zones the optical gain, represented by the imaginary part of the refractive index of this active region, is a maximum, whereas the real part of this index is a minimum. The way in which these zones are produced will be described below. Furthermore, to avoid the parasitic effects on the laser flux of photons escaping from the flared part 8, a deflector 9 is formed around the stripe 7, close to its join with the flared part 8. This deflector 9 is made up of two elements being placed symmetrically on either side of the stripe 7. Each of these two elements is in the form of a “V”, one branch of which is parallel to the stripe 7 and the other branch of which makes an angle of less than 90° to the first.

According to an alternative embodiment of the invention (not shown), it is possible for the axis of the flared part 8 not to be aligned with respect to the axis of the stripe 7 but to make an angle of a few degrees (in a plane parallel to that of the active layers) so as to reduce the reflectivity of the laser beam exit face.

FIG. 2 shows a schematic sectional view of the active transverse guiding layers of the flared part 8. These layers are referenced 10 in their entirety and flank at least one quantum well 11. An exemplary embodiment is shown in detail below with reference to FIG. 5. The material of these active layers is preserved over their entire volume (in other words, there is no removal of this material). The flared part 8 is produced by implanting protons in the zones external to this flared part that it is desired to obtain (said zones being referenced 12 and 13 in FIG. 2, on either side of the part 8), in the layers lying above the quantum well 11, making these outer zones electrically insulating, whereas the central part, corresponding to the flared part, remains conducting. If the variation in the current density along a direction perpendicular to the axis of the flared part 8 is determined, it should be noted that this variation has substantially a Gaussian profile, with a maximum at the center of the part 8, the current density being practically zero in the zones 12 and 13.

FIG. 3 shows a schematic sectional view of the active transverse guiding layers of the stripe 7. These layers are the same as those in FIG. 2 and are referenced 10 in their entirety, and they flank at least one quantum well 11. As in the case of FIG. 2, the material of these active layers is preserved over their entire volume. The stripe 7 is also produced by implanting protons in the zones external to this stripe that it is desired to obtain (the zones being referenced 12A and 13A in FIG. 3, on either side of the stripe 7), in the layers lying above the quantum well 11, making these outer zones electrically insulating, whereas the central part, corresponding to the stripe, remains conductive. The energy of these protons may be at least about 100 keV. If the variation of the current density in a direction perpendicular to the axis of the stripe 7 is determined, it is found that it has a substantially Gaussian profile, with a maximum at the center of the part 7, the current density being practically zero in the zones 12A and 13A.

FIG. 4 shows in particular the constructional details of the deflector 9. The two “Vs” of this deflector are produced by cutting, into the active layers 10 lying above the quantum well 11, “trenches” having walls perpendicular to the planes of these layers and the cross section of which, in a plane parallel to the plane of the layers, has the “V” shape described above. These trenches are then filled with a polymer material, which makes them electrically insulating.

FIG. 5 shows schematically the semiconductor structure of the laser of the invention. This structure is formed on a highly n-doped substrate N3, for example made of GaAs. The following layers are formed in succession on this substrate:
a low-index n-type layer N2 for optical and electrical confinement, which layer may be made of GaInP, GaAlAs, AlGaInP, etc.;
a high-index n-type layer N1 for electrical and optical confinement, which layer may be made of GaInAsP, GaInP, etc.;
a layer QW, which is an active quantum well layer;
a high-index p-type layer P1 for electrical and optical confinement, which layer may be made of GaInAsP, GaInP, etc.;
a low-index p-type layer P2 for optical confinement; which layer may be made of GaInP, GaAlAs, AlGaInP, etc.; and
a highly p-doped electrical contact layer P3, for example made of GaAs.

Corresponding to the diagram of the structure that has just been described, FIG. 5 shows, to the right of this structure, the curve of variation of the refractive index of the various layers that make up said structure, and also the curve of variation of the intensity of the optical field along a direction perpendicular to the planes of these layers.

FIG. 6 shows schematically the first nine steps, referenced A to I, from the twelve main steps for producing the structure of the laser of the invention. These steps are, in order:

(A): epitaxial growth of the substrate and of the following layers, as shown in FIG. 5, the combination being referenced 14;

(B): deposition of an ohmic contact 15 on the layer P3 of the structure 14;

(C): photolithography and etching of the two “Vs” of the deflector 9;

(D): thinning of the substrate (on the opposite side from the layer 15), the overall semiconductor structure now being referenced 14A;

(E): deposition of an ohmic contact 16 on the underside of the substrate;

(F): deposition of a polymer 17 in the trenches of the deflector 9 followed by removal of the surplus, so as to obtain a plane surface coplanar with the upper face of the layer 15;

(G): photolithography on the upper face of the layer 15, then proton implantation (the protons being shown symbolically by a number of spots PR), so as to define the parts 7 and 8. The zone lying beneath the photoresist part 15A remaining after the photolithography (between the two trenches) does not include protons;

(H): deposition of an electrode 18 on the layer 15;

(I): photolithography on the electrode and opening, by chemical etching, of the dicing paths 18A between adjacent unitary lasers or adjacent groups of elementary lasers;
cleavage of the faces 5 and 6;
antireflection treatment of the laser emission faces 6;
high-reflectivity treatment of the faces 5; and
separation of the elementary lasers (or of the arrays of elementary lasers) along the dicing paths 18A.

Thus, thanks to the invention, it is possible to produce elementary laser sources or laser sources grouped in arrays, and to fasten them via their upper face (face 18) to an appropriate heat sink. This considerably improves the extraction of heat in operation compared with the sources of the prior art, which can be fixed to a sink only via their base.

According to the exemplary embodiments of the invention, what are obtained are elementary lasers having wavelengths lying between 0.7 and 1.1 μm with quantum wells or boxes (called “Qdots”) on a GaAs substrate, having wavelengths lying between 1.1 and 1.8 μm with quantum wells or Qdots on an InP substrate, wavelengths lying between 2 and 2.5 μm in the case of quantum wells or Qdots on a GaSb substrate, and wavelengths lying between 3 and more than 12 μm with QCL-type laser sources.

In general, for all these exemplary embodiments, the divergence of the emitted beam was of the order of a few degrees and the power of the beam with the stripe around 200 to 300 mW and upon exiting the flared part greater than 10 W.

In one exemplary embodiment, a laser of the type described above, with a total length of 3 mm, was fabricated on a semiconductor structure, emitting at around λ=975 nm. It was provided with a high-reflectivity layer on the rear face and with a low-reflectivity layer on the front face. The exit power of the laser reached 2 W in continuous mode at 20° C. The “chip” formed by this laser had a threshold current of only 263 mA and a good external differential efficiency of 0.72 W/A. Its wall-plug efficiency reached its maximum at 43% at around 1.5 W, this being a good value for a flared semiconductor laser. These good results were maintained between 15 and 25° C. The far field of this laser was measured at about 20 cm from the laser. The emitted beam was very narrow: its width between 1° and 2° at mid-height and between 2° and 5° at 1/e². The far field profile had a very sharp peak. It is known that the threshold current of semiconductor lasers varies as exp(T/T₀). The characteristic temperature T₀ of the laser thus produced was measured, and this was 136 K between 20 and 40° C. This high value indicates that the threshold of the laser increases very little with temperature.

1. A semiconductor laser, comprising:
in an active layer, a first part in the form of a narrow monomode stripe with transverse gain guiding, terminating in a second part flaring out from the first part, said second part having transverse gain guiding.

2. The laser as claimed in claim 1, wherein the first and second parts of the cavity are formed in the active layers lying above the quantum well.

3. The laser as claimed in claim 1, wherein the first and second parts of the laser cavity are bounded by implanting protons (PR) in the zones that border them (12-13, 12A-13A).

4. The laser as claimed in claim 1, wherein including a parasitic photon deflector in the first cavity part.

5. The laser as claimed in claim 3, wherein the deflector comprises two V-shaped trenches placed on either side of the first cavity part and in that these trenches are filled with an insulating material.

6. The laser as claimed in claim 1, which is fastened to a heat sink via its face on the opposite side from the substrate.

7. A method of producing a semiconductor laser comprising a first part in the form of a narrow stripe and being extended by a second part flaring out from the first part, characterized in that it comprises the following steps:
epitaxial growth of the substrate and the following active and confinement layers, and also of an upper electrical contact layer;
deposition of an ohmic contact on the upper electrical contact layer;
thinning of the underside of the substrate;
deposition of an ohmic contact on the underside of the substrate;
deposition of a photoresist on the ohmic contact and photolithography, leaving photoresist remaining on top of a zone corresponding to said two parts of the laser;
proton implantation via the upper face of the assembly comprising the substrate and the layers formed thereon; and
deposition of an electrode on the ohmic contact.

8. The method as claimed in claim 7, wherein several unitary lasers are produced on one and the same substrate, in that an electrode is deposited on all of the unitary lasers, in that dicing paths defining the unitary lasers are scored on this electrode by photolithography, in that these paths are opened by chemically etching into this electrode and in that the elementary lasers are separated along the dicing paths.

9. The laser which claimed in claim 2, which is fastened to a heat sink via its face on the opposite side from the substrate.

10. The laser which claimed in claim 3, which is fastened to a heat sink via its face on the opposite side from the substrate.

11. The laser which claimed in claim 4, which is fastened to a heat sink via its face on the opposite side from the substrate.

12. The laser which claimed in claim 5, which is fastened to a heat sink via its face on the opposite side from the substrate.
